(19) United States
(12) Patent Application Publication
(10) Pub. No.: US 2005/0237727 A1
(43) Pub. Date: Oct. 27, 2005

(54) Radio frequency shield covers

(75) Inventor: John W. Baker, Hudson, MA (US)

Correspondence Address: Fogg and Associates, LLC, P.O. Box 581339, Minneapolis, MN, 55458-1339, US

(73) Assignee: ADC Broadband Access Systems, Inc.

(21) Appl. No.: 10/831,796

(22) Filed: Apr. 26, 2004

(51) Int. Cl. H05K 9/00

(52) U.S. Cl. 361/816; 174/35 GC

(57) ABSTRACT

A shield cover including a top surface, four side walls, each side wall extends substantially perpendicular from an edge of the top surface, and one or more first securing tabs extending from at least one of the side walls. Each of the one or more first securing tabs includes a leg and a foot, the foot including a tapered edge. Each of the one or more first securing tabs is adapted to draw the cover toward a top surface of a circuit board and reduce gaps created between the cover and the board. The board includes slots through the board to receive the securing tabs. The securing tabs are engaged by twisting the leg of the securing tab such that the tapered portion of the foot contacts a bottom surface of the board and resultantly pulls the cover toward the top surface of the board.

### TECHNICAL FIELD

The following description relates to shielding and in particular to radio frequency and electromagnetic interference shields.

### BACKGROUND

Many electronic devices such as telephones, computers, personal digital assistants, televisions and the like have components that emit electromagnetic radiation. This radiation can interfere with the operation of other electronic components within the device or other equipment closely located. Shielding is often used to minimize the electromagnetic radiation. Various types of shielding are employed and have size, shape and attachment drawbacks.

Often shielding for circuit boards leave gaps between the board and the shield and leakage can occur. Also shield covers that are secured to the circuit board using ground clips or other common attachment devices often become unfastened or loose due to vibration or handling. Sometimes the shield covers even become detached from the clips. The resulting gaps can lead to electromagnetic interference problems. In instances where a shield is soldered to the circuit board and if the electronics on the board need tuning or reworking the shield is difficult to remove and replace.

Therefore, a need exists for improved radio frequency shield covers.

### SUMMARY

A shield cover is provided. The shield cover includes a top surface, four side walls, each side wall extending substantially perpendicular from an edge of the top surface, and one or more first securing tabs extending from at least one of the side walls. Each of the one or more first securing tabs includes a leg and a foot, the foot including a tapered edge. Each of the one or more first securing tabs, when engaged, is adapted to draw the shield cover toward a top surface of an associated circuit board and reduce gaps created between the cover and the circuit board. The circuit board includes one or more slots through the circuit board to receive the one or more securing tabs. The one or more first securing tabs are engaged by twisting the leg of the securing tab such that the tapered portion of the foot contacts a bottom surface of the circuit board and resultantly pulls the shield cover toward the top surface of the circuit board.

The details of one or more embodiments of the claimed invention are set forth in the accompanying drawings and the description below. Other features and advantages will become apparent from the description, the drawings, and the claims.

### DRAWINGS

FIG. 1A is a block diagram of one embodiment of a radio frequency shield cover.

FIG. 1B is a block diagram of one embodiment of a securing foot for a radio frequency shield cover.

FIG. 2 is a block diagram of another embodiment of a radio frequency shield cover.

FIG. 3A is a block diagram of one embodiment of a portion of a radio frequency shield cover.

FIG. 3B is a block diagram of another embodiment of a portion of a radio frequency shield cover.

Like reference numbers and designations in the various drawings indicate like elements.

### DETAILED DESCRIPTION

Embodiments of the present invention provide systems and methods of radio frequency shield covers.

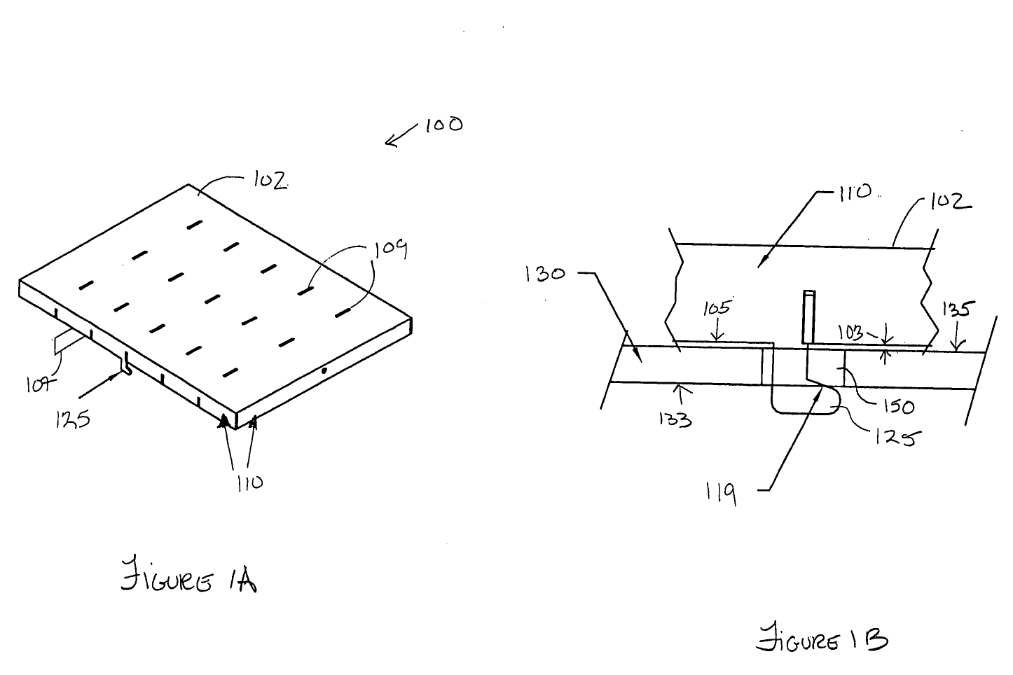

FIG. 1A is an illustration of one embodiment of a radio frequency (RF) shield cover, shown generally at 100, according to the teachings of the present invention. Shield cover 100 includes a top surface 102 with four side walls 110 extending from top surface 102. In one embodiment, side walls 110 are substantially perpendicular to top 102. Shield cover 100 further includes one or more tabs 125 that extend from side walls 110. Tabs 125 secure shield cover 100 to an associated circuit board. Tabs 125 are described in more detail with respect to FIG. 1B below.

In one embodiment, shield cover 100 includes one or more dividers 107 and a plurality of slots 109 adapted to receive or secure dividers 107. Dividers 107 partition shield cover 100 into a plurality of smaller shields used to shield selected areas of a circuit board. In one embodiment, dividers 107 are secured to shield cover 100 by spot welding, soldering, tack welding, rivets or another suitable attachment device.

FIG. 1B is a cut away view of a portion of shield cover 100 interfacing with circuit board 130. As shown, a gap 103 exists between the bottom 105 of side wall 110 and the top 135 of circuit board 130. Tab 125 is shown in detail and extends from side wall 110 of shield cover 100 and includes a tapered edge 119 for securing shield cover 100 to circuit board 130 and reducing gap 103. Tab 125 is made of a malleable material and when twisted such that tapered edge 119 comes in contact with a bottom edge 133 of circuit board 130 gap 103 is reduced. In one embodiment, the foot of tab 125 is twisted between 15 and 90 degrees as required by the specific application in order to pull cover 100 closer to circuit board 130 and reduce gap 103.

In one embodiment, side wall 110 aligns substantially flush with an outer edge of circuit board 130 and tab 125 grasps bottom of edge 133 via an outer edge or perimeter of circuit board 130. In another embodiment, circuit board 130 includes a slot 150 in circuit board 130 and tab 125 extends through slot 150 and grasps the bottom edge 133 of circuit board 130 via slot 150.

In one embodiment, shield cover 100 includes one or more of tabs 125 along side walls 110 for securing shield cover 100 to circuit board 130. In another embodiment, shield cover 100 includes one or more dividers 107 each having one or more tabs 125 extending from dividers 107 securing shield cover 100 to circuit board 130.

In operation shield cover 100 is sized for a specific application and fits onto circuit board 130 and is secured via one or more tabs 125 located along side walls 110 and/or dividers 107. In one embodiment, tabs 125 located along side walls 110 are stamped or punched from the same piece of material that cover 100 is made from. In another embodiment, tabs 125 located on dividers 107 is stamped or punched from the same piece of material that dividers 107 are made from. In one embodiment, shield cover 100 including any tabs 125 are stamped from beryllium copper, sheet brass, nickel silver, thin mild steel or the like. In another embodiment, shield cover 100 including any tabs 125 is made of a material providing EMI shielding and is suitably ductile to allow tabs 125 to be twisted up to 105 degrees without breaking off.

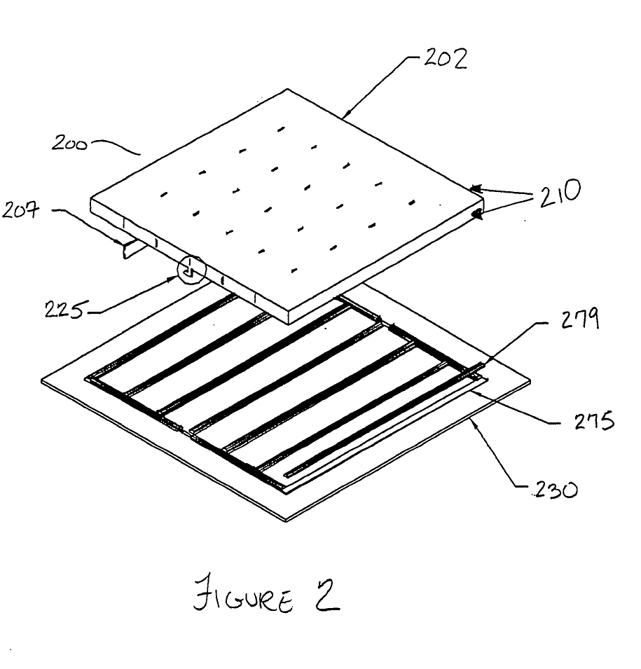

FIG. 2 is an illustration of one embodiment of an RF shield cover 200 and associated printed circuit board 230. Shield cover 200 includes a top surface 202 with four side walls 210 extending from top surface 202 and one or more securing tabs 225 extended from side walls 210. Tabs 225 are as described above with respect to FIG. 1B and secure shield cover 200 to printed circuit board 230. In one embodiment, shield cover 200 includes one or more dividers 207 that partition shield cover 200 into a plurality of smaller shield covers. In one embodiment, dividers 207 are secured to shield cover 200 by spot welding, soldering, tack welding, rivets or another suitable attachment device.

Circuit board 230 is shown with a plurality of ground etches 275 and associated gaskets 279. In one embodiment, gaskets 279 are EMI gaskets e.g. metallized nylon over foam EMI gaskets or the like. Gaskets 270 are adapted to secure to circuit board 230 and cover ground etches 275. As illustrated, gaskets 279 correspond to the outline of side walls 210 and dividers 207 so that when cover 200 is secured to circuit board 230 side walls 210 and dividers 207 align with gaskets 279. It is understood that although multiple gaskets 279 are shown to correspond with multiple dividers 207, any combination of dividers 207 and gaskets 279 may be employed as required by the specific application. Gaskets 279 aid in reducing the gap between side walls 210, and dividers 207 and circuit board 230. Tabs 225 pull shield cover 200 down to engage with and compress gaskets 279.

In one embodiment, tabs 225 located along side walls 210 are stamped or punched from the same piece of material that cover 200 is made from. In another embodiment, tabs 225, located on dividers 207, are stamped or punched from the same piece of material that dividers 207 are made from. In one embodiment, shield cover 200 including any tabs 225 are stamped from beryllium copper, sheet brass, nickel silver, thin mild steel or the like. In another embodiment, shield cover 200 including any tabs 225 is made of a material providing EMI shielding and is suitably ductile to allow tabs 225 to be twisted up to 105 degrees without breaking off.

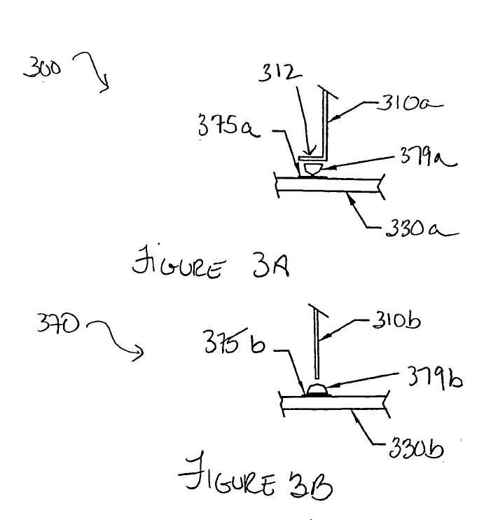

FIG. 3A is a block diagram of one embodiment of a portion of a radio frequency shield cover, shown generally at 300, according to the present invention. FIG. 3A illustrates one embodiment of a side wall 310a of a shield cover such as shield covers 100 or 200 discussed above. In this embodiment, side wall 310a includes a bottom edge 312 that is substantially perpendicular to side wall 310a. Bottom edge 312 is illustrated as interfacing with a gasket 379a that is in contact with ground etch 375a of circuit board 330a. In another embodiment, bottom edge 312 interfaces directly with circuit board 330a without a gasket such as gasket 379a.

FIG. 3B is a block diagram of another embodiment of a portion of a radio frequency shield cover, shown generally at 370, according to the present invention. FIG. 3B illustrates one embodiment of a side wall 310b of a shield cover such as shield covers 100 or 200 discussed above. In this embodiment, side wall 310b does not include a bottom edge 312 as discussed above with respect to FIG. 3A. Side wall 310b directly interfaces with a gasket 379b that is in contact with ground etch 375b of circuit board 330b. In another embodiment, side wall 310b interfaces directly with circuit board 330b without a gasket such as gasket 379b.

In one embodiment, gaskets 379a and 379b are EMI gaskets e.g. metallized nylon over foam EMI gaskets or the like.

Shield covers 100 and 200 as discussed above are secured to associated circuit boards using one or more tabs 125 and 225, respectively and reduce any gap produced between the cover and circuit board. As a result, electromagnetic radiation is reduced.

A number of embodiments of the invention defined by the following claims have been described. Nevertheless, it will be understood that various modifications to the described embodiments may be made without departing from the spirit and scope of the claimed invention. Accordingly, other embodiments are within the scope of the following claims.

1. A shield cover, comprising:
a top surface;
four side walls, each side wall extending substantially perpendicular from an edge of the top surface; and
one or more first securing tabs extending from at least one of the side walls;
wherein each of the one or more first securing tabs include a leg and a foot, the foot including a tapered edge;
wherein each of the one or more first securing tabs, when engaged, draws the shield cover toward a top surface of an associated circuit board and reduces gaps created between the shield cover and the circuit board;
wherein the circuit board includes one or more slots through the circuit board to receive the one or more securing tabs;
wherein the one or more first securing tabs are engaged by twisting the leg of the securing tab such that the tapered portion of the foot contacts a bottom surface of the circuit board and resultantly pulls the shield cover toward the top surface of the circuit board.

2. The cover of claim 1, further including one or more dividers that span the length of the shield cover.

3. The cover of claim 2, wherein each of the one or more dividers includes one or more second securing tabs extending from the dividers.

4. The cover of claim 1, wherein the top surface, four side walls and each of the one or more first securing tabs are stamped out of the same piece of material.

5. The cover of claim 4, wherein the material has electromagnetic interference properties.

6. The cover of claim 5, wherein the material is malleable.

7. The cover of claim 4, wherein the material is one of beryllium copper, sheet brass, nickel silver, and thin mild steel.

8. An apparatus, comprising:
a circuit board including electronic components that emit electromagnetic radiation;
a radio frequency shield cover adapted to provide radio frequency shielding for the circuit board, including:
a top surface;
four side walls, each side wall extending substantially perpendicular from an edge of the top surface; and
one or more first securing tabs extending from at least one of the side walls;
wherein each of the one or more first securing tabs includes a leg and a foot, the foot including a tapered edge;
wherein each of the one or more first securing tabs, when engaged, pulls the shield cover toward a top surface of the circuit board and reduces gaps created between the shield cover and the circuit board;
wherein the circuit board includes one or more slots through the circuit board that are sized to receive the one or more first securing tabs;
wherein the one or more first securing tabs are engaged by twisting the leg of the securing tab such that the tapered portion of the foot contacts a bottom surface of the circuit board and resultantly pulls the shield cover toward the top surface of the circuit board.

9. The apparatus of claim 8, further including one or more dividers that span the length of the shield cover.

10. The apparatus of claim 9, wherein each of the one or more dividers includes one or more second securing tabs extending from the dividers.

11. The apparatus of claim 8, wherein the top surface, four side walls and each of the one or more first securing tabs are stamped out of the same piece of material.

12. The apparatus of claim 11, wherein the material has electromagnetic interference properties.

13. The apparatus of claim 12, wherein the material is malleable.

14. The apparatus of claim 11, wherein the material is one of beryllium copper, sheet brass, nickel silver, and thin mild steel.

15. The apparatus of claim 10, wherein each of the one or more dividers and associated second securing tabs are stamped out of the same material.

16. The apparatus of claim 8, wherein each side wall includes a bottom edge that is substantially perpendicular to the side wall.

17. The apparatus of claim 8, wherein the circuit board includes a plurality of ground etches.

18. The apparatus of claim 17, further comprising a plurality of EMI gaskets adapted to cover the plurality of ground etches.

19. The apparatus of claim 18, wherein the EMI gaskets are employed between the side walls of the shield cover and the plurality of ground etches.

20. A radio frequency shield cover, comprising:
a top surface;
four side walls extending substantially perpendicular from the top surface; and
one or more dividers coupled between an opposing pair of side walls of the four side walls;
wherein the one or more dividers partition the shield cover into a plurality of smaller shield covers and provide radio frequency shielding for selected areas of a circuit board;
at least two securing tabs extending from the four side walls and one or more dividers;
wherein each of the at least two securing tabs include a leg and a foot, the foot including a tapered edge;
wherein each of the two or more securing tabs, when engaged, pulls the shield cover toward a top surface of the circuit board and reduces gaps created between the shield cover and the circuit board.

21. The shield cover of claim 20, wherein the top surface, four side walls and each of the securing tabs extending from the side walls are stamped out of the same piece of material,.

22. The shield cover of claim 21, wherein the material has electromagnetic interference properties.

23. The shield cover of claim 21, wherein the material is malleable.

24. The shield cover of claim 21, wherein the material is one of beryllium copper, sheet brass, nickel silver, and thin mild steel.

25. The shield cover of claim 20, wherein each of the one or more dividers and associated securing tabs are stamped out of the same material.

26. The shield cover of claim 20, wherein each side wall includes a bottom edge that is substantially perpendicular to the side wall.

27. The shield cover of claim 20, wherein the circuit board includes a plurality of ground etches.

28. The shield cover of claim 20, further comprising a plurality of EMI gaskets adapted to cover the plurality of ground etches.

29. The shield cover of claim 28, wherein the EMI gaskets are employed between the side walls of the shield cover and the plurality of ground etches.

30. A method of manufacturing a radio frequency shield cover for reducing electromagnetic radiation, the method comprising:
stamping the shield cover out of a single piece of material;
wherein the shield cover includes:
a top surface;
four side walls, each side wall extending substantially perpendicular from an edge of the top surface; and
one or more first securing tabs extending from at least one of the side walls;
wherein each of the one or more first securing tabs includes a leg and a foot, the foot including a tapered edge;
wherein each of the one or more first securing tabs, when engaged, pulls the shield cover toward a top surface of a circuit board and reduces gaps created between the shield cover and the circuit board;
cutting one or more slots through the circuit board that are sized to receive the one or more first securing tabs;
wherein the one or more first securing tabs are engaged by twisting the leg of the securing tab such that the tapered portion of the foot contacts a bottom surface of the circuit board and resultantly pulls the shield cover toward the top surface of the circuit board.
